(19) United States
(12) Patent Application Publication
(10) Pub. No.: US 2013/0176697 A1
(43) Pub. Date: Jul. 11, 2013

(54) ATTACHMENT MECHANISM FOR ELECTRONIC COMPONENT

(71) Applicants: JUN-HUI WANG, Shenzhen City (CN); KUN LI, Shenzhen City (CN); AI-LING HE, Shenzhen City (CN)

(72) Inventors: JUN-HUI WANG, Shenzhen City (CN); KUN LI, Shenzhen City (CN); AI-LING HE, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/463,830

(22) Filed: May 4, 2012

(30) Foreign Application Priority Data
Jan. 11, 2012 (CN) 201210007173.7

(51) Int. Cl. H05K 7/06

(52) U.S. Cl. 361/760

(57) ABSTRACT

An attachment mechanism for fastening an electronic component includes a circuit board and a fastener. The circuit board includes a first connector to connect with a second connector of the electronic component. A mounting hole is defined beside the first connector. The fastener includes a supporting plate. A bottom of the supporting plate includes a first protrusion abutting against a top of the circuit board, and a second protrusion deformably extending through the mounting hole to abut against a bottom of the circuit board. A top of the supporting plate includes a supporting protrusion. A pair of spaced engaging portions protrudes from a top of the supporting protrusion. The engaging portions extend through the mounting hole to allow the electronic component to be supported on the supporting protrusion.

### CROSS-REFERENCE TO RELATED APPLICATIONS

Relevant subject matter is disclosed in seven pending U.S. patent applications, all titled “ATTACHMENT MECHANISM FOR ELECTRONIC COMPONENT”, respectively filed on Mar. 20, 2012, with the application Ser. No. 13/424,390; on Mar. 22, 2012, with the application Ser. No. 13/426,629; on Mar. 23, 2012, with the application Ser. No. 13/427,923; on Mar. 29, 2012, with the application Ser. No. 13/434,791; on Apr. 12, 2012, with the application Ser. No. 13/444,874; on Apr. 13, 2012, with the application Ser. No. 13/445,935; and on Apr. 23, 2012, with the application Ser. No. 13/452,956, which are assigned to the same assignee as this patent application.

### BACKGROUND

1. Technical Field

The present disclosure relates to a mechanism for attaching an electronic component to a device.

2. Description of Related Art

An electronic component, such as an expansion card, in an electronic device, is attached to a motherboard. An end of the expansion card is connected to the motherboard by a connector, and an opposite end of the expansion card is fastened to the motherboard with screws. Mounting the expansion card to the motherboard with screws is inefficient and requires the use of a tool, such as a screwdriver, which is inconvenient.

### BRIEF DESCRIPTION OF THE DRAWINGS

Many aspects of the present embodiments can be better understood with reference to the drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an exemplary embodiment of an attachment mechanism, together with an electronic component, wherein the attachment mechanism includes a fastener.

FIG. 2 is an enlarged view of the fastener of FIG. 1.

FIG. 3 is an inverted view of FIG. 2.

FIG. 4 is an assembled, isometric view of FIG. 1, and viewed from a different perspective.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

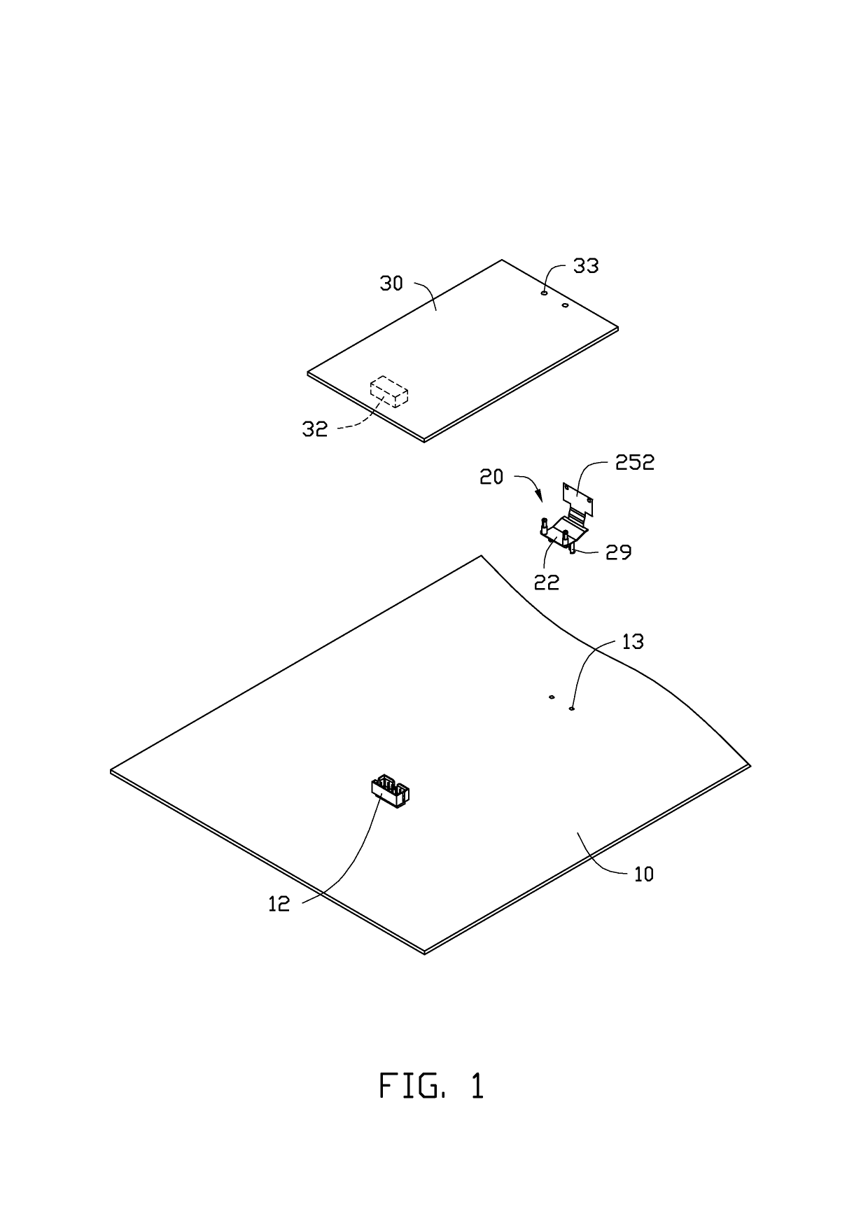

FIG. 1 shows an exemplary embodiment of an attachment mechanism for fastening an electronic component 30. The attachment mechanism includes a circuit board 10, and a fastener 20.

A first connector 12 is fastened to the circuit board 10. Two mounting holes 13 are defined in the circuit board 10, beside the first connector 12.

The electronic component 30 includes a second connector 32 mounted to a first end of a bottom surface of the electronic component 30, and two through holes 33 defined in a second end of the electronic component 30 opposite to the first end.

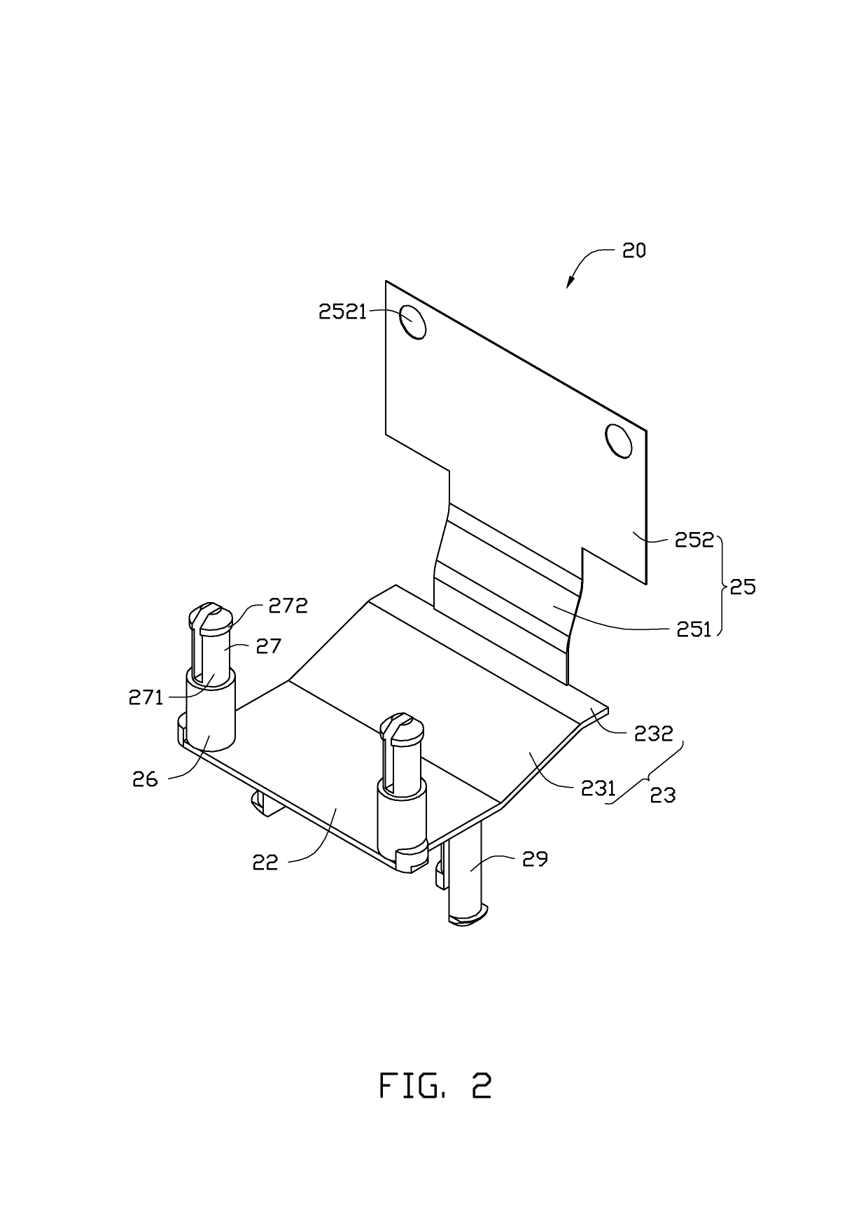

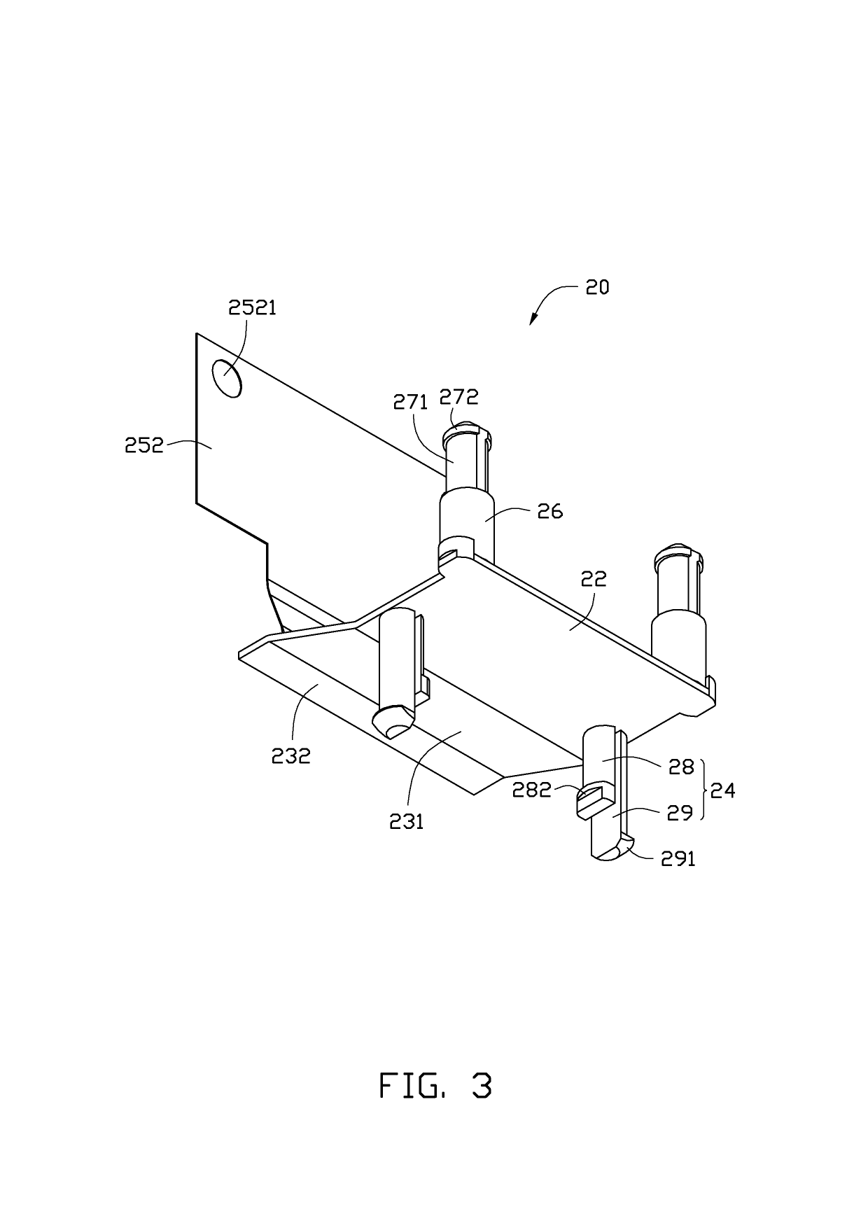

FIGS. 2 and 3 show the fastener 20 including a rectangular supporting plate 22, a T-shaped operation portion 25, and a connection portion 23 located between the supporting plate 22 and the operation portion 25. The connection portion 23 includes an extension plate 231 slantingly extending up from a first side of the supporting plate 22, and a connection plate 232 extending from a side of the extension plate 231 away from the supporting plate 22. The connection plate 232 is parallel to the supporting plate 22. The operation portion 25 extends up from a side of the connection plate 232 away from the extension plate 231. The operation portion 25 includes a resilient tab 251 extending up from the connection plate 232, and a stop plate 252 connected to a top of the resilient tab 251, perpendicular to the connection plate 232. Two through holes 2521 are defined in a top portion of the stop plate 252.

Two supporting protrusions 26 respectively protrude up from two corners of the supporting plate 22 near a second side of the supporting plate 22 opposite to the first side. A pair of spaced and opposite engaging portions 27 perpendicularly extends up from a top surface of each supporting protrusion 26. Each engaging portion 27 includes a semi-cylindrical neck 271, and a tapered head 272 formed on a top of the neck 271. A lower portion of each head 272 is larger than the neck 271 and smaller than an upper portion of the head 272. Two feet 24 perpendicularly extend down from two corners of the supporting plate 22 near the first side. Each foot 24 includes a semi-cylindrical first protrusion 28 and a spaced semi-cylindrical second protrusion 29. The first protrusion 28 is shorter than the second protrusion 29. A stop tab 282 and a tapered head 291 are respectively formed at distal ends of the first protrusion 28 and the second protrusion 29, opposite to each other. An upper portion of the head 291 is larger than the second protrusion 29 and a lower portion of the head 291.

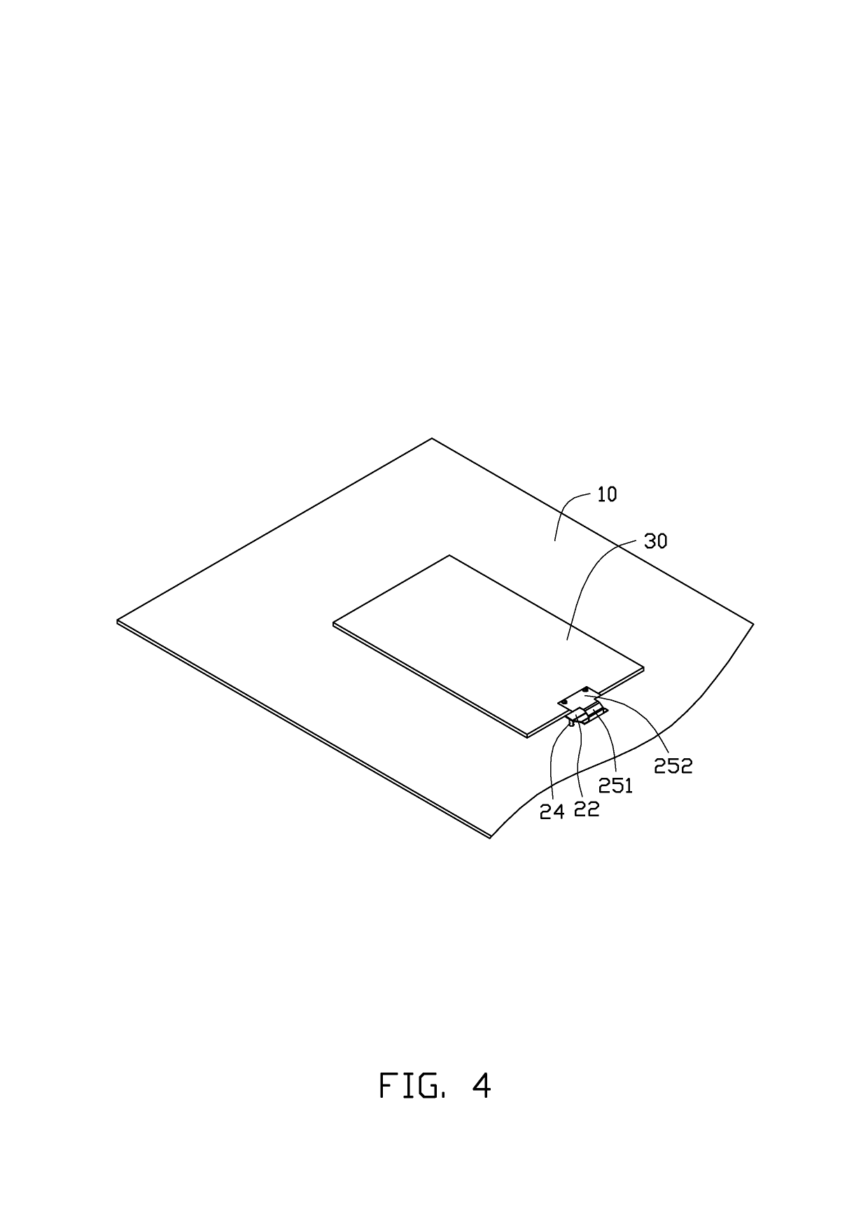

FIG. 4 shows in assembly, the second protrusions 29 are respectively deformed to extend through the mounting holes 13, with sidewalls of the tapered heads 291 gradually sliding along the circuit board 10 bounding the mounting holes 13. The heads 291 abut against a bottom surface of the circuit board 10 and the stop tabs 282 abut against a top surface of the circuit board 10. Thereby, the fastener 20 is attached to the circuit board 10.

The electronic component 30 is placed on the circuit board 10, with the second connector 32 connected with the first connector 12, the engaging portions 27 extended through the corresponding through holes 33. The electronic component 30 is supported on the supporting protrusions 26. The resilient tab 251 is bent to allow the stop plate 252 to rotate toward the engaging portions 27. The two pairs of engaging portions 27 are deformed to extend the tapered heads 272 through the corresponding through holes 2521 so that the stop plate 252 abuts against bottoms of the heads 272 and a top of the electronic component 30. Thereby, the electronic component 30 is fastened to the circuit board 10.

It is believed that the present embodiments and their advantages will be understood from the foregoing description, and various changes may be made thereto without departing from the spirit and scope of the description or sacrificing all of their materials advantages, the examples hereinbefore described merely being exemplary embodiments.

What is claimed is:

1. An attachment mechanism for fastening an electronic component, comprising:
a circuit board comprising a first connector to connect with a second connector of the electronic component, and a mounting hole defined beside the first connector; and
a fastener comprising a supporting plate, and an operation portion rotatable relatively to the supporting plate, a bottom of the supporting plate comprising a first protrusion abutting against a top of the circuit board, and a second protrusion deformably extending through the mounting hole to abut against a bottom of the circuit board, a top of the supporting plate comprising a supporting protrusion, and a pair of spaced engaging portions protruding from a top of the supporting protrusion, the engaging portions extending through the mounting hole to allow the electronic component to be supported on the supporting protrusion, the operation portion operable to rotate to engage with the engaging portions such that the operation portion stops a top of the electronic component.

2. The attachment mechanism of claim 1, wherein a connection portion is located between the supporting plate and the operation portion, the connection portion comprises an extension plate slantingly extending up from the supporting plate, and a connection plate extending from the extension plate, parallel to the supporting plate, the operation portion extends up from the connection plate.

3. The attachment mechanism of claim 2, wherein the operation portion comprises a resilient tab extending from the connection plate, and a stop plate connected to a distal end of the resilient tab, the resilient tab is operable to bend to allow the stop plate to rotate to stop the top of the electronic component.

4. The attachment mechanism of claim 3, wherein the stop plate defines a through hole, each engaging portion comprises a semi-cylindrical neck and a tapered head formed on a top of the neck, a lower portion of the head is larger than the neck and smaller than an upper portion of the head, the engaging portions are deformed to extend the heads through the through hole to allow the stop plate to abut against bottoms of the heads.

5. The attachment mechanism of claim 1, wherein a stop tab perpendicularly extends from the first protrusion to abut against the top of the circuit board, a tapered head is formed on the second protrusion to extend through the mounting hole and abut against the bottom of the circuit board.

6. The attachment mechanism of claim 5, wherein an upper portion of the head is larger than the second protrusion and a lower portion of the head, the second protrusion is deformed to extend the head through the mounting hole to allow the head to abut against the bottom of the circuit board.

7. An attachment mechanism for fastening an electronic component, comprising:
a circuit board comprising a first connector to connect with a second connector of the electronic component, and two mounting holes defined beside the first connector; and
a fastener comprising a supporting plate, and an operation portion rotatable relatively to the supporting plate, a bottom of the supporting plate comprising two feet, each foot comprising a first protrusion abutting against a top of the circuit board, and a second protrusion deformably extending through a corresponding mounting hole to abut against a bottom of the circuit board, a top of the supporting plate comprising two supporting protrusions, and a pair of spaced engaging portions protruding from a top of each supporting protrusion, the engaging portions extending through the corresponding mounting holes to allow the electronic component to be supported on the supporting protrusions, the operation portion operable to rotate to engage with the engaging portions such that the operation portion stops a top of the electronic component.

8. The attachment mechanism of claim 7, wherein a connection portion is located between the supporting plate and the operation portion, the connection portion comprises an extension plate slantingly extending up from the supporting plate, and a connection plate extending from the extension plate, parallel to the supporting plate, the operation portion extends up from the connection plate.

9. The attachment mechanism of claim 8, wherein the operation portion comprises a resilient tab extending from the connection plate, and a stop plate connected to a distal end of the resilient tab, the resilient tab is operable to bend to allow the stop plate to rotate to stop the top of the electronic component.

10. The attachment mechanism of claim 9, wherein the stop plate defines two through holes, each engaging portion comprises a semi-cylindrical neck and a tapered head formed on a top of the neck, a lower portion of the head is larger than the neck and smaller than an upper portion of the head, the engaging portions are deformed to extend the heads through the corresponding through holes to allow the stop plate to abut against bottoms of the heads.

11. The attachment mechanism of claim 8, wherein the supporting plate is rectangular, the feet are respectively at two corners near the connection portion, the supporting protrusions are respectively at two corners away from the connection portion.

12. The attachment mechanism of claim 7, wherein a stop tab perpendicularly extends from each first protrusion to abut against the top of the circuit board, a tapered head is formed on the second protrusion to extend through the mounting hole and abut against the bottom of the circuit board.

13. The attachment mechanism of claim 12, wherein an upper portion of each head is larger than the corresponding second protrusion and a lower portion of the head, the second protrusions are deformed to extend the heads through the corresponding mounting holes to allow the heads to abut against the bottom of the circuit board.
